(19) United States
(12) Patent Application Publication
(10) Pub. No.: US 2010/0032194 A1
(43) Pub. Date: Feb. 11, 2010

(54) PRINTED WIRING BOARD, MANUFACTURING METHOD FOR PRINTED WIRING BOARD AND ELECTRONIC DEVICE

(75) Inventor: Hisashi KATO, Ogaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: IBIDEN CO., LTD., Ogaki-shi (JP)

(21) Appl. No.: 12/495,033

(22) Filed: Jun. 30, 2009

Related U.S. Application Data
(60) Provisional application No. 61/087,256, filed on Aug. 8, 2008.

(51) Int. Cl. H05K 1/16; H05K 1/11; H05K 3/00

(52) U.S. Cl. 174/260; 174/263; 29/843

(57) ABSTRACT

A printed wiring board including an insulation layer, a pad formed in the insulation layer, a solder bump formed over the pad, and a metallic film interposed between the pad and the solder bump and covering at least a portion of the top surface and/or the side surface of the pad over the insulation layer. The pad has a via land portion and a via conductor portion. The insulation layer has the first surface, the second surface on the opposite side of the first surface and a via-hole extending between the first surface and the second surface. The via land portion of the pad is formed over the second surface of the insulation layer. The via conductor portion of the pad is filling the via-hole of the insulation layer.

### CROSS-REFERENCE TO RELATED APPLICATIONS

The present application claims the benefits of priority to U.S. application Ser. No. 61/087,256, filed Aug. 8, 2008. The contents of that application are incorporated herein by reference in their entirety.

### BACKGROUND OF THE INVENTION

1. Field of the Invention

The present invention is related to a printed wiring board that mainly mounts chip components (e.g., chip capacitors, chip resistors, chip inductors).

2. Discussion of the Background

Conventionally, chip components such as a chip capacitor are mounted on a printed wiring board through a reflow process.

For example, in Japanese Patent Laid-Open Publication H11-8453, a substrate to mount a chip component is described, which is made up of a circuit substrate, pads to secure the electrodes of an electronic component formed on a surface of the circuit substrate, and solder formed on the pads. The contents of this publication are incorporated herein by reference in their entirety.

### SUMMARY OF THE INVENTION

According to one aspect of the present invention, a printed wiring board including an insulation layer, a pad formed in the insulation layer, a solder bump formed over the pad, and a metallic film interposed between the pad and the solder bump and covering the top surface and/or the side surface of the pad over the insulation layer. The pad has a via land portion and a via conductor portion. The insulation layer has the first surface, the second surface on the opposite side of the first surface and a via-hole extending between the first surface and the second surface. The via land portion of the pad is formed over the second surface of the insulation layer. The via conductor portion of the pad is filling the via-hole of the insulation layer.

According to another aspect of the present invention, a method for manufacturing a printed wiring board includes preparing a structure having an insulation layer having the first surface, the second surface on the opposite side of the first surface and a via-hole extending between the first surface and the second surface, and a pad having a via land portion formed over the second surface of the insulation layer and a via conductor portion filling in the via-hole of the insulation layer, forming a metallic film covering at least a portion of the top surface and/or the side surface of the pad over the second surface of the insulation layer, and forming a solder bump on the metallic film.

According to yet another aspect of the present invention, an electronic device includes a printed wiring board having a solder connection structure, and an electronic component mounted to the printed wiring board via the solder connection structure. The printed wiring board has an insulation layer, a pad formed in the insulation layer, and a metallic film interposed between the pad and the solder connection structure and covering at least a portion of the top surface and/or the side surface of the pad over the insulation layer. The pad has a via land portion and a via conductor portion. The insulation layer has the first surface, the second surface on the opposite side of the first surface and a via-hole extending between the first surface and the second surface. The via land portion of the pad is formed over the second surface of the insulation layer. The via conductor portion of the pad is filling the via-hole of the insulation layer. The solder connection structure is formed over the pad.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 shows views showing the structure of a printed wiring board according to the First Embodiment;

FIG. 2 shows views to illustrate a method for manufacturing a printed wiring board according to the First Embodiment;

FIG. 3 shows views to illustrate a method for manufacturing a printed wiring board according to the First Embodiment;

FIG. 4 shows views to illustrate a method for manufacturing a printed wiring board according to the First Embodiment;

FIG. 5 is a view showing another example of a metallic film;

FIG. 6 is a perspective view of a chip capacitor mounted in a printed wiring board;

FIG. 7(a) is a view showing a stage in which a chip capacitor is mounted on a printed wiring board, and FIG. 7(b) is a view showing a stage in which the printed wiring board and the chip capacitor are bonded after reflow;

FIG. 8 is a view showing the structure of a printed wiring board according to the Second Embodiment;

FIG. 9 shows views to illustrate a method for manufacturing a printed wiring board according to the Second Embodiment;

FIG. 10 shows views to illustrate a method for manufacturing a printed wiring board according to the Second Embodiment; and

FIG. 11 is a view showing another example of mounting an IC chip.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

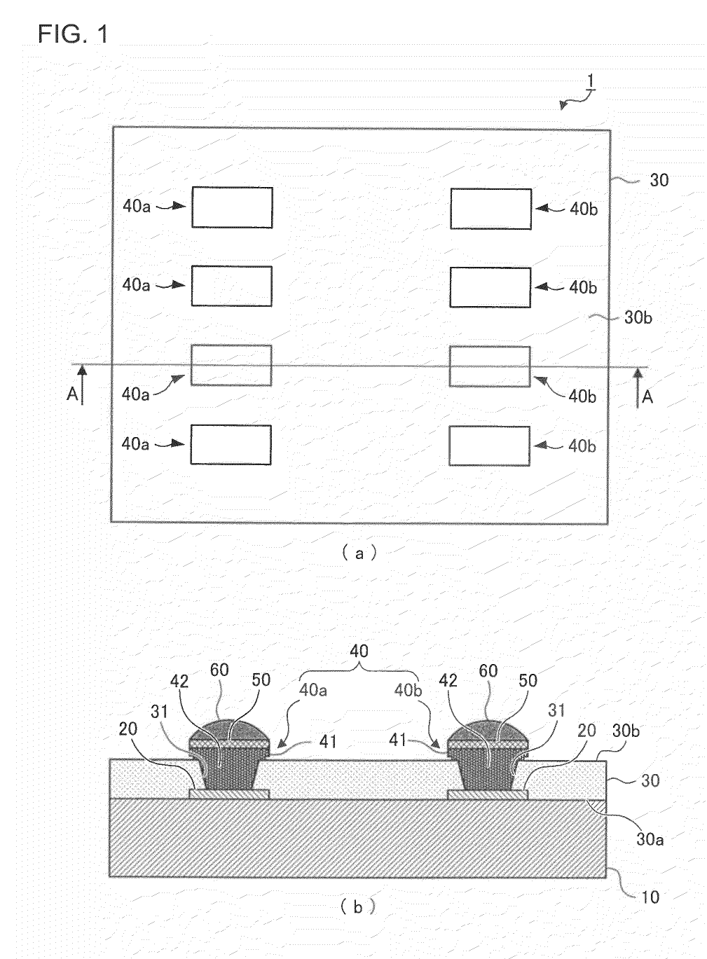

First, the structure of printed wiring board 1 according to the First Embodiment is described. FIG. 1 shows views showing the structure of printed wiring board 1 according to the First Embodiment: FIG. 1(a) is a plan view; and FIG. 1(b) is a cross-sectional view seen from the A-A line in FIG. 1(a).

As shown in FIG. 1(b), printed wiring board 1 according to the present embodiment has resin substrate 10 as an insulation layer made by impregnating glass fabric with resin and curing it, conductive circuit 20 formed on resin substrate 10, and resin insulation layer 30 formed on resin substrate 10 and conductive circuit 20. In resin insulation layer 30, via-holes 31 for via conductors reaching conductive circuit 20 are formed. Also, resin insulation layer 30 has first surface (30a) being in contact with resin substrate 10 and conductive circuit 20, and second surface (30b) opposite first surface (30a). Second surface (30b) is exposed to the outside.

Also, printed wiring board 1 has multiple pads 40 to mount an electronic component. Pad 40 is made up of via land 41 formed on second surface (30b) of resin insulation layer 30, and via conductor (filled via) 42 filled in via-hole 31. On at least part of the top and side surfaces of pad 40, metallic film 50 is formed. On metallic film 50, solder bump 60 is formed. An electronic component is secured onto pads 40 through solder bumps 60.

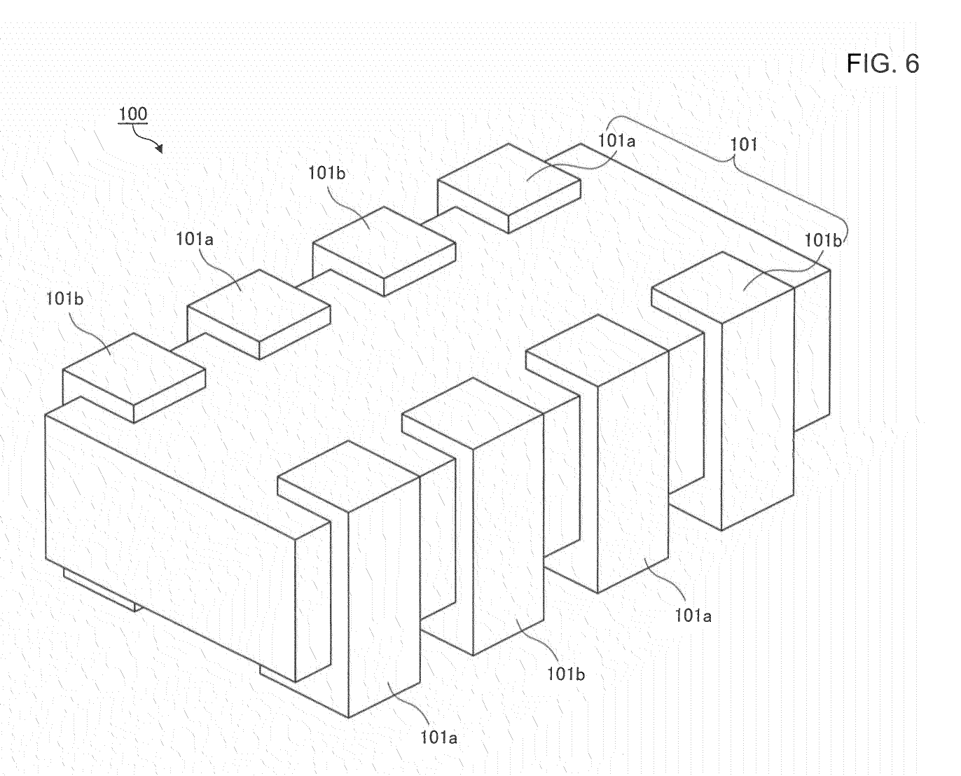

Pads 40 of printed wiring board 1 are formed at the same time terminals (the circuit to mount an IC chip), which are not shown in the drawings, are patterned. Then, printed wiring board 1 may mount chip capacitor 100 (see FIG. 6) through soldering; the chip capacitor has multiple plus electrodes (101a) and multiple minus electrodes (101b). To mount the chip capacitor shown in FIG. 6, printed wiring board 1 has multiple first pads and multiple second pads. The first pads are connected to the plus electrodes of the chip capacitor through solder bumps. The number of first electrodes is the same as that of the plus electrodes. The second pads are connected to the minus electrodes of the chip capacitor through solder bumps. The number of second electrodes is the same as that of the minus electrodes (see FIGS. 1). Printed wiring board 1 may also mount a chip capacitor having one plus electrode and one minus electrode.

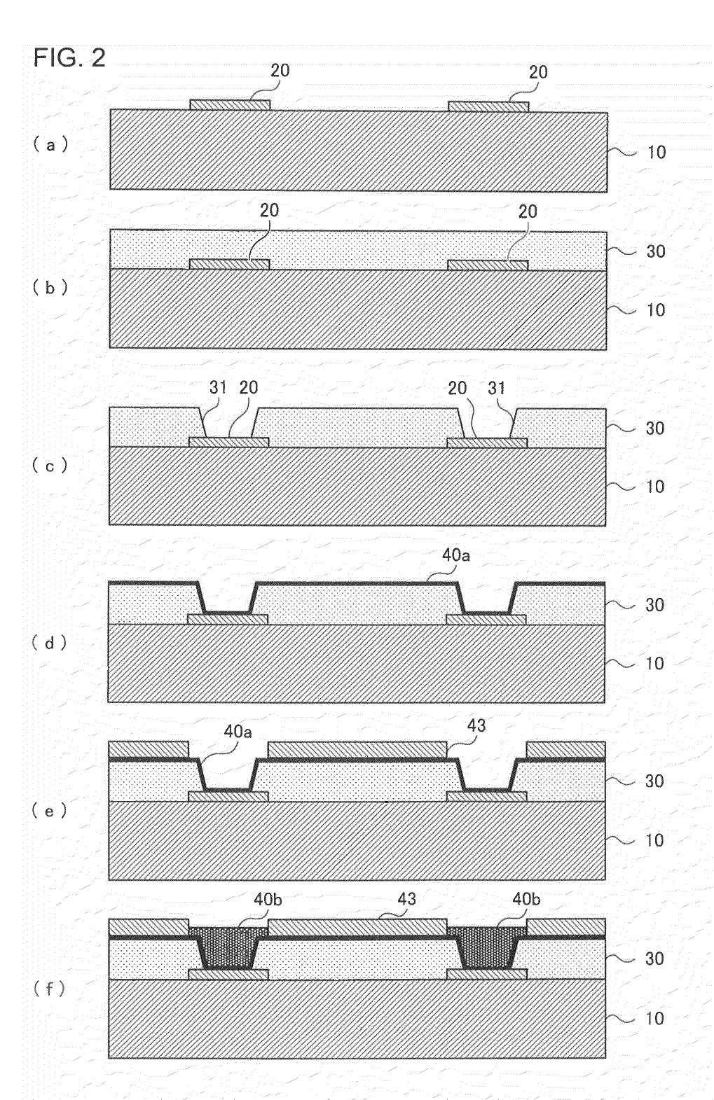

Next, a method for manufacturing printed wiring board 1 according to the present embodiment is described. FIGS. 2-4 are views to illustrate a method for manufacturing printed wiring board 1.

On resin substrate 10 with conductive circuit 20 formed on its surface (see FIG. 2(a)), resin insulation layer 30 is formed (FIG. 2(b)). As for a resin insulation layer, an ABF film (made by Ajinomoto Fine-Techno Co., Inc.) may be used. An ABF film is laminated on resin substrate 10 under the lamination conditions of temperature at 50-150° C. and pressure at 0.5-1.5 MPa. Then, through thermosetting, the ABF film becomes a resin insulation layer. Alternatively, the resin insulation layer may be formed by applying a thermosetting resin and curing it. As for the resin, in addition to a thermosetting resin, a thermoplastic resin, a photosetting resin that is a thermosetting resin part of which is photosensitive, an ultraviolet-setting resin, and a resin compound of such resins (such as a compound of thermosetting resin and thermoplastic resin) may also be used.

Next, in resin insulation layer 30, via-holes 31 reaching conductive circuit 20 are formed using a CO₂ laser, UV-YAG laser or the like (FIG. 2(c)).

Next, on the surface of resin substrate 10 where resin insulation layer 30 having via-holes 31 is formed, electroless copper plating is performed to form electroless copper-plated film (40a) (FIG. 2(d)). Then, photoresist 43 is formed on electroless copper-plated film (40a). After that, photoresist 43 is patterned by being exposed to light and developed using a pattern mask (FIG. 2(e)). In the following, electrolytic copper plating is performed to form electrolytic copper-plated film (40b) in the area where photoresist 43 is not formed (FIG. 2(f)).

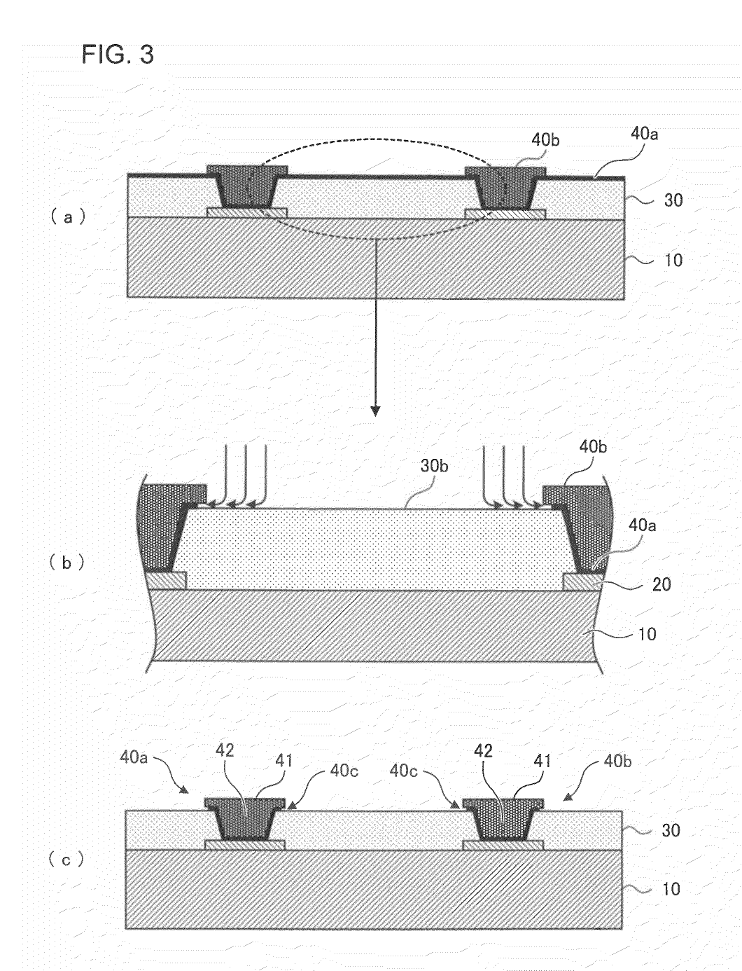

Then, photoresist 43 is removed and electroless copper-plated film (40a) where photoresist 43 existed is etched away. FIG. 3 shows views showing the etching process. Etching is conducted by spraying an etching solution on the substrate where the spaces between electrolytic copper-plated films (40b) are connected with electroless copper-plated film (40a). By doing so, the area of electroless copper-plated film (40a) (the electroless copper-plated film between electrolytic copper-plated films (40b)) where photoresist 43 existed is removed first. Since electroless copper-plated film (40a) is etched away more easily than electrolytic copper-plated film (40b), as shown in FIG. 3(b), part of electroless copper-plated film (40a) underneath electrolytic copper-plated film (40b) is removed. As a result, as shown in FIG. 3(c), electrolytic copper-plated film (40b) protrudes beyond electroless copper-plated film (40a) in a direction parallel to second surface (30b) (the direction toward the periphery of via conductor 42), and space (40c) is formed between resin insulation layer 30 and electrolytic copper-plated film (40b). As shown in FIG. 3(c), electrolytic copper-plated film (40b) of pad 40 is made up of a portion formed on electroless copper-plated film (40a) and of a portion protruding beyond electroless copper-plated film (40a) (there is a space between electrolytic copper-plated film (40b) and resin insulation layer 30). The direction in which electrolytic copper-plated film (40b) protrudes is opposite via conductor 42.

The size of space (40c) may be changed by adjusting the time of etching.

Also, as for an etching solution, the following is preferred to be used: a sulfuric acid-hydrogen peroxide solution, a persulfate solution such as ammonium persulfate, sodium persulfate or potassium persulfate, an iron (II) chloride solution or a copper (II) chloride solution.

Then, through the process so far, on the side of second surface (30b) of resin substrate 30 opposite resin substrate 10, pads 40 are formed which are made up of via lands 41 and via conductors (filled vias) 42 filled in via-holes 31.

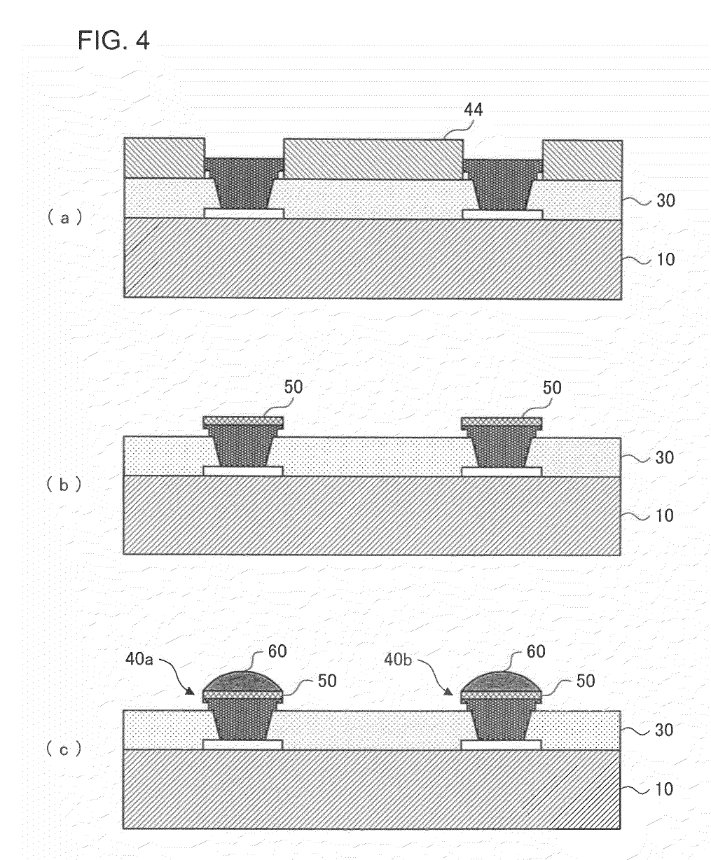

Next, on the top and side surfaces of pad 40, metallic film 50 is formed. As for metallic film 50, for example, a tin film may be used. When forming a tin film, photoresist 44 is formed first on resin insulation layer 30. Next, photoresist 44 is patterned by being exposed to light and developed using a pattern mask (FIG. 4(a)). In the following, the substrate is immersed in a tin substitution solution to form a tin film on the surface of electrolytic copper-plated film (40a). As for a tin substitution solution, for example, a tin substitution solution containing stannous fluoroborate and thiourea may be used. After that, photoresist 44 is removed (FIG. 4(b)). In doing so, a tin film functioning as metallic film 50 is formed on part of the top and side surfaces of pad 40.

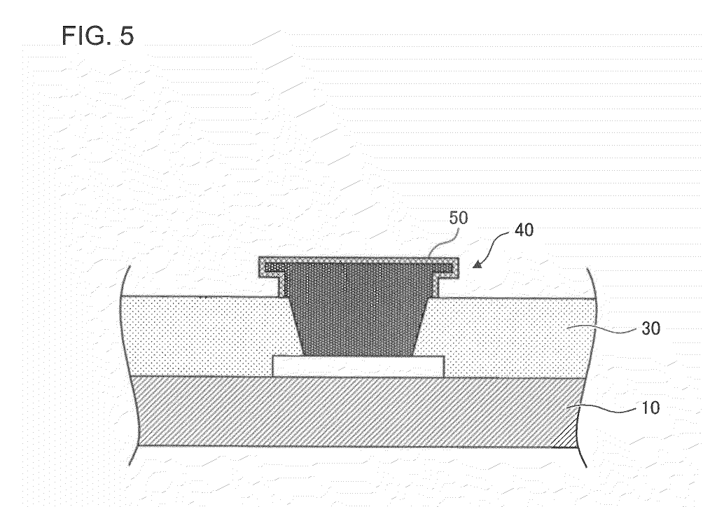

FIG. 5 is a view showing another example of metallic film 50. FIG. 5 is an example in which metallic film 50 is formed on the entire surfaces of pad 40. In FIG. 5, unlike FIG. 4(a), patterned photoresist 44 is not used. A substrate (FIG. 3(c)) where the surfaces (top and side surfaces) of pad 40 are exposed is immersed in a tin substitution solution. As a result, a tin film may be formed on the entire surfaces of pad 40. In doing so, a tin film functioning as metallic film 50 may be formed on the entire top and side surfaces of pad 40 (FIG. 5).

Other than tin, as a material for metallic film 50, gold, palladium, nickel, silver or platinum may be selected. When the material is selected for metallic film 50, it is preferred to be selected according to the material (in the present embodiment, the material (such as copper, silver, tungsten or molybdenum) of electrodes 101 of chip capacitor 100) of the part which is soldered in an electronic component mounted on printed wiring board 1. Namely, the materials are preferred to be selected so that the solder wettability to metallic film 50 is greater than the solder wettability to the relevant parts (electrodes 101 in chip capacitor 100) of the electronic component. If the electrodes of chip capacitor 100 are made of paste, and pads 40 are made of copper, forming metallic film 50 on pads 40 is optional.

Next, solder paste is printed on pad 40. After that, solder bump 60 is formed on the surface of pad 40 through a reflow process at 200° C. (FIG. 4(c)). If metallic film 50 is formed on the entire surfaces (top surface and side walls) of pad 40, solder bump 60 may most likely be formed on the entire surfaces (top surface and side walls) of pad 40; if metallic film 50 is formed on the top surface of pad 40, a solder bump may most likely be formed on the top surface of pad 40.

Next, an example of how to use printed wiring board 1 is described.

FIG. 6 is a perspective view of chip capacitor 100 mounted on printed wiring board 1. As shown in FIG. 6, chip capacitor 100 has multiple electrodes 101. Electrodes 101 are made up of plus electrodes (positive electrodes) (101a) and minus electrodes (negative electrodes) (101b). It is preferred that plus electrodes and minus electrodes be formed alternately.

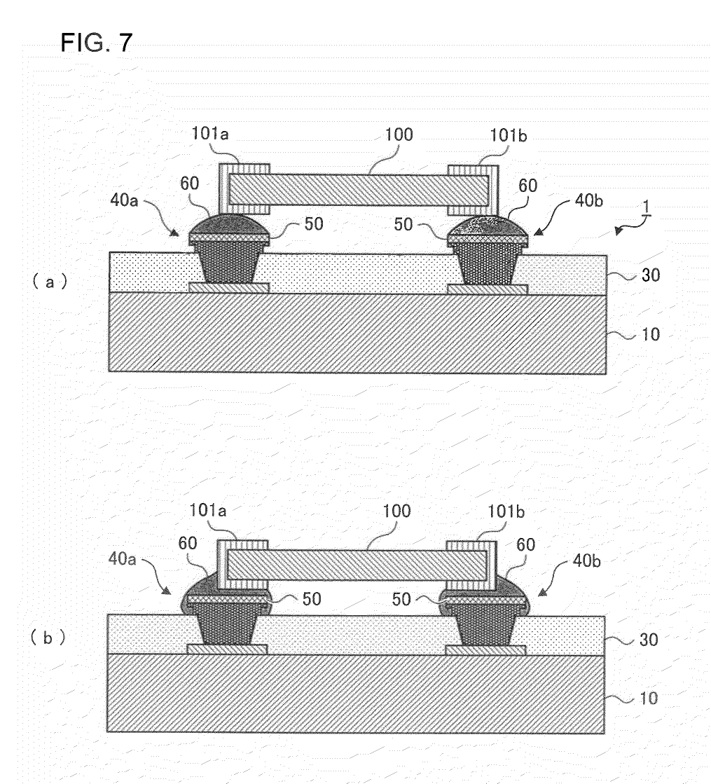

Chip capacitor 100 is placed on solder bumps 60 on pads 40 of printed wiring board 1. Plus electrodes (101a) of chip capacitor 100 correspond one-to-one to pads 40 of printed wiring board 1 to be connected to the plus electrodes. Minus electrodes (101b) of chip capacitor 100 correspond one-to-one to pads 40 of printed wiring board 1 to be connected to the minus electrodes. FIG. 7(a) is a view showing a stage in which chip capacitor 100 is placed on printed wiring board 1.

Reflow is conducted after chip capacitor 100 has been mounted on printed wiring board 1. In doing so, printed wiring board 1 and chip capacitor 100 are bonded via solder (solder connection structure). FIG. 7(b) is a view showing a stage in which chip capacitor 100 is mounted on printed wiring board 1.

The side walls of pads 40 of printed wiring board 1 are exposed. Thus, during the reflow, solder is spread on the side walls of pads 40 from the top surfaces of pads 40 toward the surface of the resin insulation layer (the second surface of the second insulation layer) (see FIG. 7(b)). Accordingly, an electronic component such as chip capacitor 100 mounted on pads 40 is pulled toward the surface of printed wiring board 1, thus making it difficult for the Manhattan phenomenon to occur (The size of pads in a conventional printed wiring board for securing the electrodes of an electronic component may be formed larger than the size of the electrodes of the electronic component so that the connection strength would be ensured between the printed wiring board and the electronic component. However, if the size of pads for securing electrodes is large, the timing of solder fusing may differ in each pad when mounting an electronic component on a printed wiring board through reflow process. Accordingly, the electronic component stands upright, and so-called Manhattan phenomenon may occur.). By making the solder wettability to the side walls of pads 40 greater than the solder wettability to electrodes 101 of chip capacitor 100, the tensile strength to pull the electronic component in the direction of the substrate may be increased. A method for such is to form metallic film 50 on the side walls of the pads and to select the materials for the electrodes and the surfaces of pads 40. For example, when the electrodes are made of paste, pads 40 may be made of copper, or a metallic film such as Sn may be formed on the surfaces of pads 40. When comparing between a case in which metallic film 50 is not formed on the side walls of pads 40 and a case in which metallic film 50 is formed, the tensile strength to pull the electronic component toward the substrate is greater in the latter case.

Pad 40 in the First Embodiment has filled via 42. Therefore, pad 40 in the First Embodiment has a larger volume when compared with pad made up only of a conductive circuit on the resin insulation layer. Accordingly, pad 40 in the First Embodiment has a large thermal capacity. As a result, the solder on each pad 40 may fuse substantially at the same time, making it difficult for the Manhattan phenomenon to occur. The outline of via land 41 (the configuration shown in FIG. 1(a)) may be made larger than the outline of electrode 101 of chip capacitor 100 to reduce the effect of electrodes on solder fusing. The solder on each pad 40 may likely fuse substantially at the same time, and the connection strength between an electronic component and printed wiring board 1 is increased.

If there is a protruding portion in a pad, a space is formed between the protruding portion and the surface of the printed wiring board (the second surface of the second insulation layer). By forming solder in such a space, the connection strength between the pad and the solder bump is increased.

Through such as above, when mounting an electronic component on printed wiring board 1, the Manhattan phenomenon may be suppressed from occurring. Also, the electronic component may be maintained with sufficient connection strength.

Also, such an effect may be achieved when mounting an electronic component having multiple plus electrodes (101a) and multiple minus electrodes (101b), such as chip capacitor 100 as shown in the present embodiment. When mounting an electronic component having multiple plus electrodes (101a) and multiple minus electrodes (101b), such as chip capacitor 100, it is usually difficult to synchronize the timing to fuse the solder on each pad. However, by using printed wiring board 1 according to the present embodiment, the timing to fuse the solder on all the pads may be synchronized. Thus, the occurrence of the Manhattan phenomenon may be suppressed, while maintaining chip capacitor 100 with sufficient connection strength. The same effect may be achieved when mounting on printed wiring board 1 an electronic component such as a chip capacitor having one plus electrode and one minus electrode.

### Second Embodiment

Next, printed wiring board 200 according to the Second Embodiment is described.

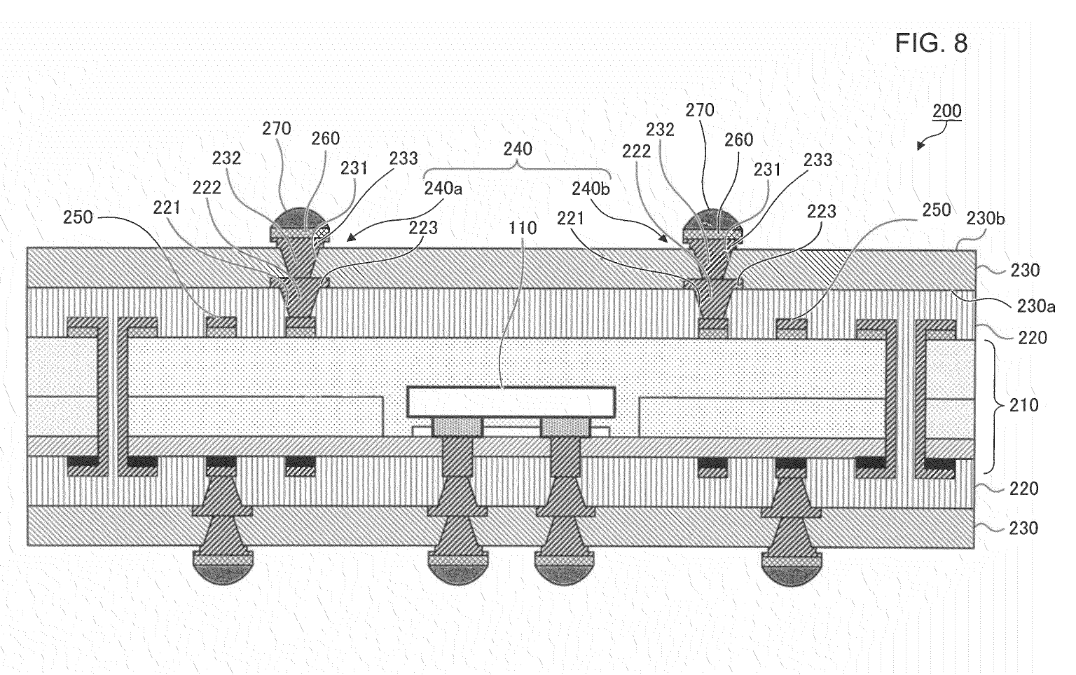

FIG. 8 is a view showing the structure of printed wiring board 200 according to the Second Embodiment.

As shown in FIG. 8, printed wiring board 200 according to the present embodiment is a multilayer printed wiring board having core substrate 210 to accommodate IC chip 110, inner-layer interlayer resin insulation layer 220 and outer-layer interlayer resin insulation layer 230.

On core substrate 210, conductive circuit 250 is formed. On core substrate 210 and conductive circuit 250, inner-layer interlayer resin insulation layer 220 is formed. Inner-layer interlayer resin insulation layer 220 has via-holes 221 for via conductor reaching conductive circuit 250. On inner-layer interlayer resin insulation layer 220, conductive circuit 223 is formed. Conductive circuit 250 and conductive circuit 223 are connected through filled vias 222 filled in via-holes 221.

Also, outer-layer interlayer resin insulation layer 230 having via-holes 231 is formed on inner-layer interlayer resin insulation layer 220 and conductive circuit 223. Via lands 233 are formed on outer-layer interlayer resin insulation layer 230. Via lands 233 are connected to conductive circuit 223 or filled vias 222 through filled vias 232 filled in via-holes 231. Also, outer-layer interlayer resin insulation layer 230 has first surface (230a), which is the surface on the side of core substrate 210, and second surface (230b) opposite first surface (230a). Second surface (230b) is exposed to the outside.

In printed wiring board 200 according to the Second Embodiment, pad 240 to mount an electronic component is made up of via conductor (filled via) 232, filled in via-hole 231 in outer-layer interlayer resin insulation layer 230, and via land 233. Metallic film 260 is formed on at least part of the top and side surfaces of pad 240. Solder bump 270 is formed on metallic film 260.

Printed wiring board 200 according to the Second Embodiment has also multiple pads 240 to mount an electronic component such as chip capacitor 100 the same as in printed wiring board 1 of the First Embodiment. Pads 240 are made up of first pads (240a) and second pads (240b). The number of first pads (240a) is the same as that of plus electrodes (101a) of chip capacitor 100; and the number of second pads (240b) is the same as that of minus electrodes (101b) of chip capacitor 100. Solder bumps 270 to secure the electronic component are formed on pads 240.

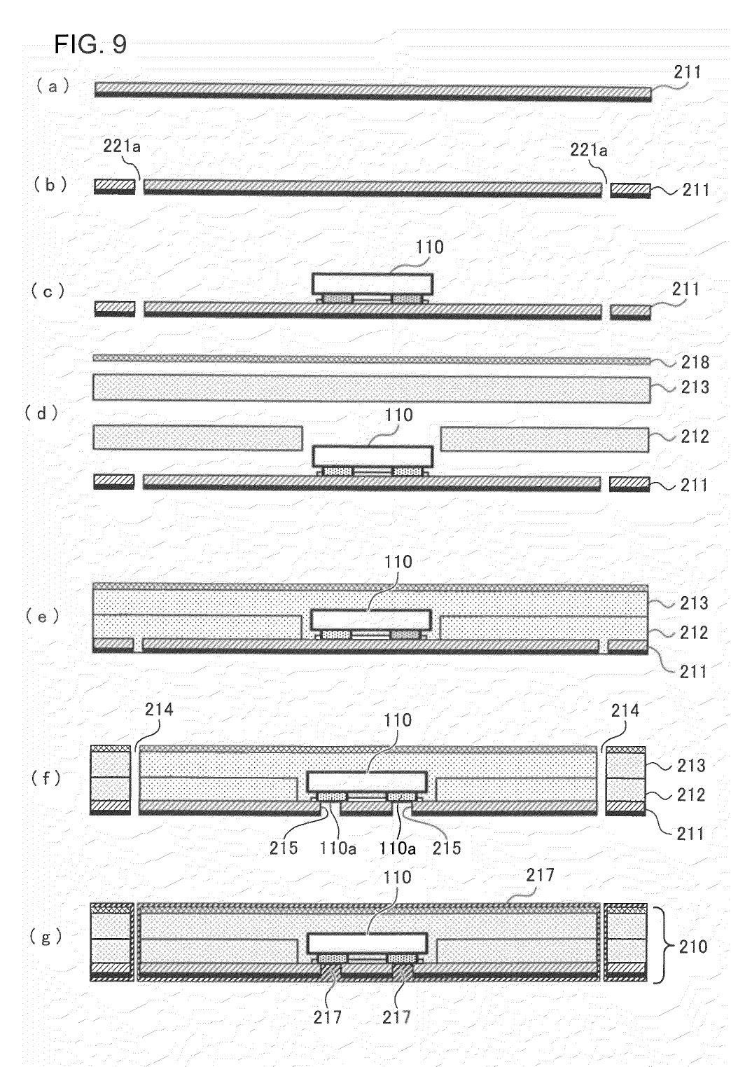

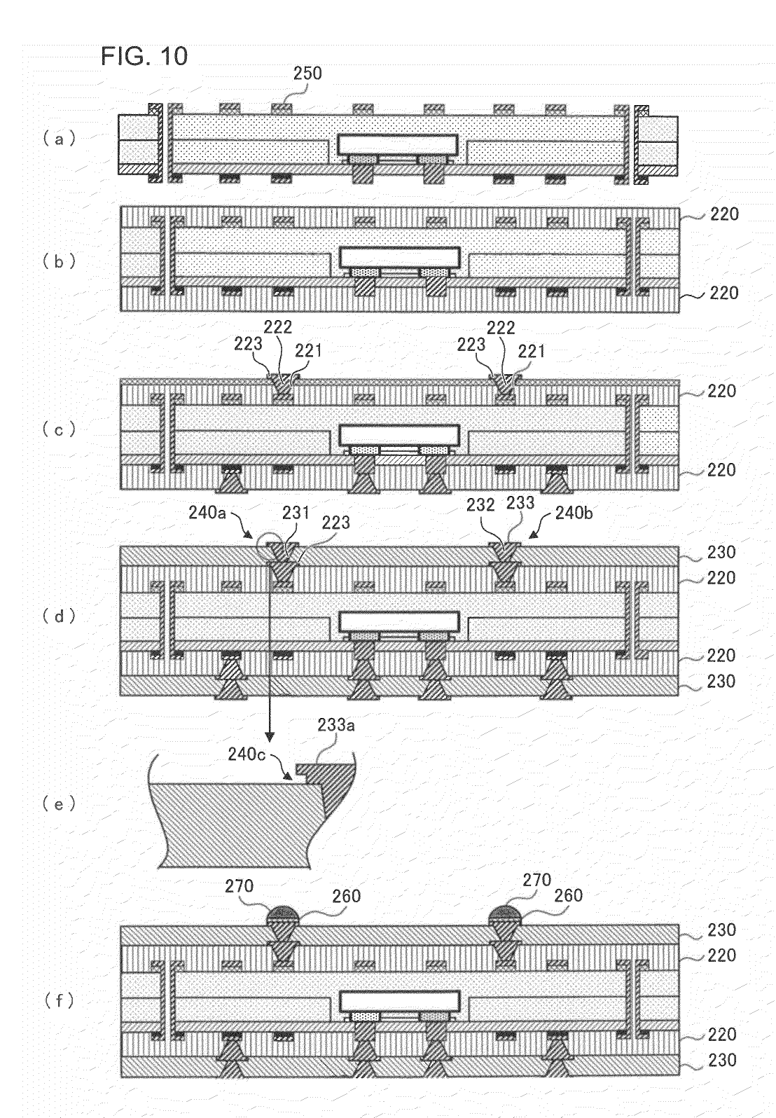

Next, a method for manufacturing printed wiring board 200 according to the Second Embodiment is described. FIGS. 9-10 are views to illustrate a method for manufacturing printed wiring board 200.

First, a method for manufacturing core substrate 210 is described using FIGS. 9.

As for a resin substrate, single-sided copper-clad laminate 211 made with an insulation layer and a copper foil is prepared (FIG. 9(a)). Next, through-holes (211a) for alignment are formed in single-sided copper-clad laminate 211 (FIG. 9(b)). Then, IC chip 110 is secured using an adhesive agent on single-sided copper-clad laminate 211 (FIG. 9(c)). After that, insulation resin 212 having an opening to accommodate IC chip 110, insulation resin 213 and copper foil 218 are laminated on the single-sided copper-clad laminate (FIG. 9(d)). Then, by thermal pressing, single-sided copper-clad laminate 211, insulation resin 212, insulation resin 213 and copper foil 218 are integrated. Thus, IC chip 110 is built into the core substrate made up of insulation layer of single-sided copper-clad laminate 211, insulation resin 212 and insulation resin 213 (FIG. 9(e)).

Next, through-holes 214 that penetrate the core substrate are formed. Then, via-holes 215 are formed that penetrate single-sided copper-clad 211 and the adhesive agent, and reach electrode terminals (110a) of IC chip 110 (FIG. 9(f)). After that, an electroless plated film (an electroless copper-plated film) is formed on the copper foil (such as 218), on the inner walls of through-holes 214 and the inner walls of via-holes 215. Then, electrolytic plated film (electrolytic copper-plated film) 217 is formed on the electroless plated-film (FIG. 9(g)).

Next, a photoresist is formed on electrolytic copper-plated film 217. The photoresist is then exposed to light and developed through a pattern mask to be patterned. Then, an etching process is conducted to form conductive circuit 250 on the core substrate (FIG. 10(a)). At the same time, via conductors are formed that connect conductive circuit 250 on the core substrate and the electrodes of IC chip 110.

After that, inner-layer interlayer resin insulation layer 220 is formed on conductive circuit 250 and core substrate 210 (FIG. 10(b)). Next, using a laser, via-holes 221 reaching conductive circuit 250 are formed in inner-layer interlayer resin insulation layer 220. Then, electroless copper plating and electrolytic copper plating are performed to form filled vias 222 and conductive circuit 223 (FIG. 10(c)). Conductive circuit 250 on the core substrate and conductive circuit 223 on inner-layer interlayer resin insulation layer 220 are connected through filled vias 222. Since the specific method for forming via-holes 221, conductive circuit 223 and filled vias 222 is the same as that for forming via-holes 31, via lands 41 and filled vias 42 of printed wiring board 1 in the First Embodiment, its detailed description is omitted.

In the following, outer-layer interlayer resin insulation layer 230 is formed on conductive circuit 223 and inner-layer interlayer resin insulation layer 220. Via-holes 231 reaching conductive circuit 223 or filled vias 222 are formed in outer-layer interlayer resin insulation layer 230. Then, electroless copper plating and electrolytic copper plating are performed to form pads 240 (FIG. 10(d)). Pad 240 is made up of filled via 232 and via land 233. When forming via land 233, an etching process is conducted after performing electrolytic copper plating. During that time, by adjusting the etching time, space (240c) may be formed between outer-layer interlayer resin insulation layer 230 and electrolytic copper-plated film (233a) of via land 233, the same as in printed wiring board 1 according to the First Embodiment (FIG. 10(e)).

Since the specific method for forming via-hole 231, via land 233 and filled via 232 is the same as that for forming via-hole 31, via land 41 and filled via 42 of printed wiring board 1 in the First Embodiment, its detailed description is omitted.

In the following, on at least part of the top and side surfaces of pad 240, metallic film 260 is formed. After that, solder bump 270 is formed (FIG. 10(f)). Since the specific method for forming metallic film 260 and solder bump 270 is the same as that for forming metallic film 50 and solder bump 60 of printed wiring board 1 in the First Embodiment, its detailed description is omitted.

Printed wiring board 200 according to the Second Embodiment is manufactured through the processes described so far.

Printed wiring board 200 manufactured above may mount an electronic component such as chip capacitor 100 on pads 240 through solder bumps 270. In printed wiring board 200, other than chip capacitor 100 (see FIG. 6) having multiple plus electrodes (101a) and multiple minus electrodes (101b), a chip capacitor having one plus electrode and one minus electrode may be mounted. The electrodes of the chip capacitor and pads correspond one-to-one.

Printed wiring board (a printed wiring board according to the Second Embodiment) 200 manufactured as above has pads 240, the same type of pads as in printed wiring board 1 according to the First Embodiment. Therefore, printed wiring board 200 of the Second Embodiment has the same effect as in printed wiring board 1 of the First Embodiment. Accordingly, the Manhattan phenomenon seldom occurs and the connection strength between an electronic component and the printed wiring board is high.

Also, printed wiring board 200 according to the Second Embodiment has built-in IC chip 110. Thus, by mounting chip capacitor 100 on printed wiring board 200, electric power may be supplied from chip capacitor 100 to IC chip 110.

Also, in a printed wiring board that has a core substrate, an inner-layer interlayer resin insulation layer on the core substrate and an outer-layer interlayer resin insulation layer on the inner-layer interlayer resin insulation layer, it is preferred that the materials for the inner-layer interlayer resin insulation layer and for the outer-layer interlayer resin insulation layer be the same. For example, in printed wiring board 200 according to the Second Embodiment, the materials for inner-layer interlayer resin insulation layer 220 and for outer-layer interlayer resin insulation layer 230 are preferred to be the same. The reason is as follows: Namely, since pads 240 have filled vias 232, at the time of a reflow process when mounting chip capacitor 100, heat is conveyed to inner-layer conductive circuit 223 (filled vias 222 formed in inner-layer interlayer resin insulation layer 220 or conductive circuit 223 formed on inner-layer interlayer resin insulation layer 220), which is connected to pads 240 via filled vias 232. Therefore, the temperatures tend to increase in outer-layer interlayer resin insulation layer 230 around pads 240 and inner-layer interlayer resin insulation layer 223 around inner-layer conductive circuit 223 connected to filled vias 232 of pads 240. If outer-layer interlayer resin insulation layer 230 and inner-layer interlayer resin insulation layer 220 are heated, their temperatures differ from that of core substrate 210. Accordingly, printed wiring board 200 may warp due to the different thermal expansion coefficients. However, if outer-layer interlayer resin insulation layer 230 and inner-layer interlayer resin insulation layer 220 are made of the same material, they are likely to warp in the same way when printed wiring board 200 warps. Therefore, the top surfaces of multiple pads 240 may be positioned at substantially the same level. As a result, high mounting productivity of electronic components such as chip capacitor 100 may be achieved.

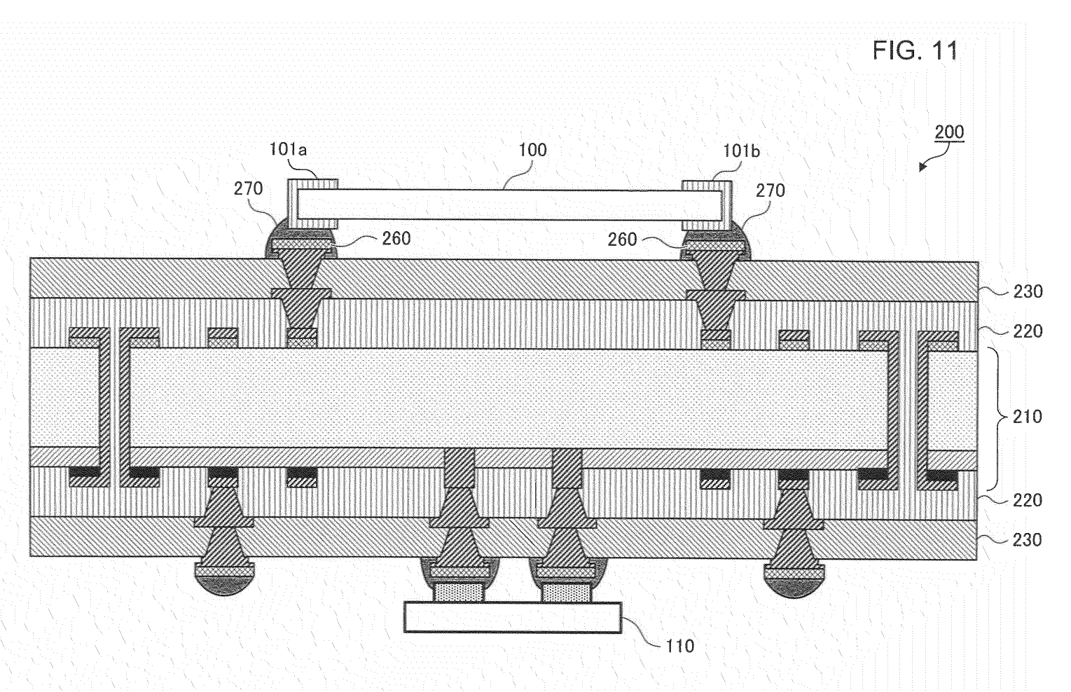

In printed wiring board 200 according to the Second Embodiment as described above, IC chip 110 is mounted by building it into the board. However, the present invention is not limited to such. FIG. 11 is a view showing another example of mounting IC chip 110. As shown in FIG. 11, IC chip 110 may be mounted using solder bumps formed on the surface opposite a surface on which chip capacitor 100 is mounted.

A printed wiring board according to an embodiment of the present invention is formed with the following: a first insulation layer; a first conductive circuit formed on the first insulation layer; a second insulation layer having a first surface on the side of the first conductive circuit and a second surface opposite the first surface and exposed to the outside, in which a via-hole for a via conductor is formed; multiple pads having via lands formed on the second surface of the second insulation layer and via conductors filled in the via-holes; a metallic film formed on at least part of the top and side surfaces of each one of the multiple pads; and a solder bump formed on the metallic film.

A method for manufacturing a printed wiring board according to another embodiment of the present invention is made up of the following: a step to form a conductive circuit on a first insulation layer; a step to form on the first insulation layer and the conductive circuit a second insulation layer having a first surface on the side of the conductive circuit and a second surface opposite the first surface and exposed to the outside; a step to form a via-hole for a via conductor in the second insulation layer; a step to form a land on the second surface of the second insulation layer; a step to form a pad made up of the land and the conductor by filling the via-hole with conductor; a step to form a metallic film on at least part of the top and side surfaces of each pad; and a step to form a solder bump on the metallic film.

An electronic component according to yet another embodiment of the present invention is formed with a printed wiring board having solder and an electronic component mounted on the printed wiring board via the solder. The printed wiring board is formed with the following: a first insulation layer; a conductive circuit formed on the first insulation layer; a second insulation layer having a first surface on the side of the conductive circuit and a second surface opposite the first surface and exposed to the outside, in which a via-hole for a via conductor is formed; multiple pads having via lands formed on the second surface of the second insulation layer and via conductors filled in the via-holes; a metallic film formed on at least part of the top and side surfaces of each of the multiple pads; and the solder on the metallic film.

According to the embodiments of the present invention, a printed wiring board may be provided that suppresses the Manhattan phenomenon from occurring, while maintaining an electronic component with sufficient connection strength.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board comprising:
an insulation layer;
a pad formed in the second insulation layer;
a solder bump formed over the pad; and
a metallic film interposed between the pad and the solder bump and covering at least a portion of at least one of a top surface and a side surface of the pad over the second insulation layer,
wherein the pad has a via land portion and a via conductor portion, the insulation layer has a first surface, a second surface on an opposite side of the first surface and a via-hole extending between the first surface and the second surface, the via land portion of the pad is formed over the second surface of the insulation layer, and the via conductor portion of the pad is filling the via-hole of the insulation layer.

2. The printed wiring board according to claim 1, further comprising:
a first insulation layer; and
a first conductive circuit formed over the first insulation layer,
wherein the insulation layer is formed over the first insulation layer and the first conductive circuit, and the first surface of the insulation layer faces the first conductive circuit.

3. The printed wiring board according to claim 1, wherein the via land portion of the pad comprises an electroless plated film and an electrolytic plated film over the second surface of the insulation layer, the electrolytic plated film of the via land portion has a portion formed on the electroless plated film and a protruding portion protruding beyond the electroless plated film in a direction parallel to the second surface, and the protruding portion of the via land portion forms a space with the insulation layer.

4. The printed wiring board according to claim 2, further comprising a third insulation layer formed between the first insulation layer and the insulation layer, and a third conductive circuit formed between the insulation layer and the third insulation layer, wherein the insulation layer and the third insulation layer are made of a same material, and the via conductor portion of the pad is connected to the third conductive circuit.

5. The printed wiring board according to claim 1, wherein the solder bump comprises a connecting member which mounts a chip capacitor having a plurality of electrodes.

6. The printed wiring board according to claim 5, wherein the metallic film has a solder wettability which is better than a solder wettability of the electrodes of the chip capacitor.

7. The printed wiring board according to claim 1, wherein the solder bump comprises a connecting member which mounts a chip capacitor having a plurality of positive electrodes and a plurality of negative electrodes, the pad is provided in a plurality, the plurality of pads includes a plurality of first pads and a plurality of second pads, the plurality of first pads is provided in a same number as the plurality of positive electrodes, and the plurality of second pads is provided in a same number as the plurality of negative electrodes.

8. The printed wiring board according to claim 6, wherein the pad has an outline which is larger than an outline of one of the electrodes facing the pad.

9. The printed wiring board according to claim 1, wherein the metallic film is formed on an entire side surface of the pad.

10. The printed wiring board according to claim 4, wherein the metallic film is formed on an entire side surface of the pad.

11. The printed wiring board according to claim 5, further comprising an IC chip mounted over the second surface of the insulation layer.

12. The printed wiring board according to claim 5, further comprising an IC chip accommodated inside the second surface of the insulation layer.

13. The printed wiring board according to claim 1, wherein the first insulation layer comprises a resin substrate comprising a glass fabric impregnated and cured with a resin.

14. A method for manufacturing a printed wiring board, comprising:
preparing a structure comprising an insulation layer having a first surface, a second surface on an opposite side of the first surface and a via-hole extending between the first surface and the second surface, and a pad having a via land portion formed over the second surface of the insulation layer and a via conductor portion filling in the via-hole of the insulation layer;
forming a metallic film covering at least a portion of at least one of a top surface and a side surface of the pad over the second surface of the insulation layer; and
forming a solder bump on the metallic film.

15. The method for manufacturing a printed wiring board according to claim 14, wherein the structure further comprises a first insulation layer and a first conductive circuit formed over the first insulation layer, the insulation layer is formed over the first insulation layer and the first conductive circuit, and the first surface of the insulation layer faces the first conductive circuit.

16. The method for manufacturing a printed wiring board according to claim 15, wherein the preparing of the structure comprises forming the conductive circuit on the first insulation layer, the second insulation layer on the first insulation layer and the conductive circuit, the via-hole in the second insulation layer, and the pad by filling the via-hole with a conductor material.

17. The method for manufacturing a printed wiring board according to claim 14, wherein the forming of the pad comprises forming an electroless plated film on the second surface of the insulation layer, forming an electrolytic plated film on the electroless plated film, and etching a portion of the electroless plated film underneath the electrolytic plated film from a side-wall side of the pad over the second surface of the insulation layer.

18. An electronic device comprising:
a printed wiring board having a solder connection structure; and
an electronic component mounted to the printed wiring board via the solder connection structure,
wherein the printed wiring board comprises an insulation layer, a pad formed in the insulation layer, and a metallic film interposed between the pad and the solder connection structure and covering at least a portion of at least one of a top surface and a side surface of the pad over the insulation layer, the pad has a via land portion and a via conductor portion, the insulation layer has a first surface, a second surface on an opposite side of the first surface and a via-hole extending between the first surface and the second surface, the via land portion of the pad is formed over the second surface of the insulation layer, the via conductor portion of the pad is filling the via-hole of the insulation layer, and the solder connection structure is formed over the pad.

19. The electronic device according to claim 18, wherein the printed wiring board further comprises a first insulation layer and a first conductive circuit formed over the first insulation layer, the insulation layer is formed over the first insulation layer and the first conductive circuit, and the first surface of the insulation layer faces the first conductive circuit.
